(19) United States
(12) Patent Application Publication
(10) Pub. No.: US 2026/0173945 A1
(43) Pub. Date: Jun. 18, 2026

(54) PACKAGE STRUCTURE

(71) Applicant: Advanced Semiconductor Engineering, Inc., Kaohsiung (TW)

(72) Inventor: Cheng-Ling HUANG, Taoyuan (TW)

(73) Assignee: Advanced Semiconductor Engineering, Inc., Kaohsiung (TW)

(21) Appl. No.: 18/983,208

(22) Filed: Dec. 16, 2024

(51) Int. Cl. H01L 23/00

(52) U.S. Cl. CPC H10W 72/90; H10W 72/019; H10W 72/20; H10W 72/01935; H10W 72/01951; H10W 72/07255; H10W 72/224; H10W 72/2528; H10W 72/29; H10W 72/923; H10W 72/934; H10W 72/952; H10W 72/9528; H10W 80/754; H10W 90/724

(57) ABSTRACT

A package structure is provided. The package structure includes a first substrate, a first dielectric layer, and a first conductive element. The first dielectric layer is over the first substrate and has an opening defined by a sloped sidewall. The first conductive element is in the opening and has an upper surface. The first conductive element includes a first portion over the sloped sidewall and a second portion distinct from the first portion. The first portion and the second portion include a plurality of first nanotwinned layers and second nanotwinned layers stacked substantially along different respective directions defining an angle of greater than 0° and less than 90°. The upper surface includes two surface portions each being an upper surface of the first portion and an upper surface of the second portion of the first conductive element, and the two surface portions have different widths in a cross-sectional view.

### BACKGROUND

### 1. Technical Field

The present disclosure relates generally to a package structure. Specifically, the present disclosure relates to a package structure including a nanotwinned copper (NT-Cu) pad.

### 2. Description of the Related Art

Currently, one or more nanotwinned copper (NT-Cu) pads may be formed on one or more aluminum (Al) pads on a chip or substrate for electrically connecting to another chip or substrate through solder joints or bonding wires. A NT-Cu pad may be formed in an opening defined by a dielectric layer over an Al pad. The opening may have a tapered cross-sectional profile defined by inclined surfaces of the dielectric layer, and portions of the NT-Cu pad formed on the inclined surfaces may have irregular crystal structures. The irregular crystal structures may have relatively poor mechanical and electrical characteristics, which may be disadvantageous to the connection between the NT-Cu pad and a solder material or a metal material. Therefore, a technical solution is needed to solve the above technical problems.

### SUMMARY

In one or more arrangements, a package structure includes a first substrate, a first dielectric layer, and a first conductive element. The first dielectric layer is over the first substrate and has an opening defined by a sloped sidewall. The first conductive element is disposed in the opening and has an upper surface. The first conductive element includes a first portion over the sloped sidewall and a second portion distinct from the first portion. The first portion includes a plurality of first nanotwinned layers stacked substantially along a first direction. The second portion includes a plurality of second nanotwinned layers stacked substantially along a second direction. An angle defined by the first direction and the second direction is greater than 0° and less than 90°. The upper surface includes a first surface portion, which is an upper surface of the first portion and has a first width in a cross-sectional view. The upper surface further includes a second surface portion, which is an upper surface of the second portion and has a second width greater than the first width in the cross-sectional view.

In one or more arrangements, a package structure includes a first substrate and a first conductive element. The first substrate includes a first pad. The first conductive element is disposed over the first pad and has an upper surface. The first conductive element includes an anisotropic crystal structure having the upper surface. A cross-sectional width of a [111] crystallographic plane of the upper surface of the anisotropic crystal structure is greater than a cross-sectional width of a non-[111] crystallographic plane of the upper surface of the anisotropic crystal structure.

In one or more arrangements, a package structure includes a first substrate, a first seed layer, and a first conductive element. The first seed layer is over the first substrate and has a curved lateral surface. The first conductive element is disposed on the first seed layer and includes an anisotropic crystal structure. The first conductive element includes a first portion that contacts the curved lateral surface and has a [111] crystallographic plane that is non-parallel to an upper surface of the first conductive element. The anisotropic crystal structure of the first conductive element further includes a second portion that is spaced apart from the curved lateral surface of the first seed layer by the first portion.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure in accordance with some arrangements of the present disclosure.

FIG. 2A is a cross-section of a portion of a package structure in accordance with some arrangements of the present disclosure.

FIG. 2A1 is a cross-section of a portion of a package structure in accordance with some arrangements of the present disclosure.

FIG. 2A2 is a cross-section of a portion of a package structure in accordance with some arrangements of the present disclosure.

FIG. 2B is a cross-section of a portion of a package structure in accordance with some arrangements of the present disclosure.

FIG. 2C is a cross-section of a portion of a package structure in accordance with some arrangements of the present disclosure.

FIG. 2D is a cross-section of a portion of a package structure in accordance with some arrangements of the present disclosure.

FIG. 3A, FIG. 3B, FIG. 3C, FIG. 3D, FIG. 3E, FIG. 3F, and FIG. 3G illustrate various stages of an example of a method for manufacturing a package structure in accordance with some arrangements of the present disclosure.

FIG. 4A, FIG. 4B, FIG. 4C, FIG. 4D, FIG. 4E, and FIG. 4F illustrate various stages of an example of a method for manufacturing a package structure in accordance with some arrangements of the present disclosure.

FIG. 5A, FIG. 5B, FIG. 5C, FIG. 5D, FIG. 5E, FIG. 5F, and FIG. 5G illustrate various stages of an example of a method for manufacturing a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

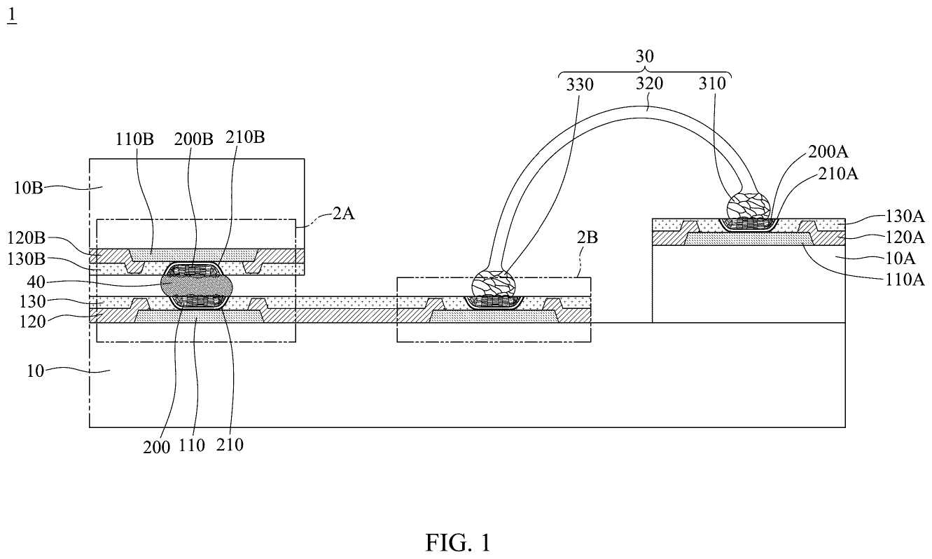

FIG. 1 is a cross-section of a package structure 1 in accordance with some arrangements of the present disclosure. The package structure may include substrates 10, 10A, and 10B, conductive pads 110, 110A, and 110B, dielectric layers 120, 120A, 120B, 130, 130A, and 130B, conductive elements 200, 200A, and 200B, seed layers 210, 210A, and 210B, a conductive wire 30, and a reflowable element 40.

When nanotwinned copper (NT-Cu) pads or layers (e.g., the conductive elements 200, 200A, and 200B) are formed in an opening defined by a dielectric layer (e.g., the dielectric layers 130, 130A, and 130B), the opening may have a tapered cross-sectional shape defined by sloped or inclined inner sidewalls. As a result, nanotwinned layers of grains of the NT-Cu pad formed over the inclined inner sidewalls may be stacked toward an inner portion of the NT-Cu pad instead of stacked upwards toward a bonding surface of the NT-Cu pad. Accordingly, the nanotwinned layers of grains formed over the inclined inner sidewalls of the dielectric layer may form irregular or less orderly crystal structures (e.g., isotropic crystal structures). The irregular or less orderly crystal structures may cause the NT-Cu pad to have a relatively loose structure, a relatively low structural strength, and a relatively low structural stability, and thus the portion with irregular or less orderly crystal structures may be easily oxidized, which is disadvantageous to the electrical performance. In addition, when the NT-Cu is bonded to another conductive pad (e.g., another NT-Cu pad), the bonding speed of the nanotwinned layers on the inclined inner sidewall and the bonding speed of the nanotwinned layers on a relatively flat surface are different, which may adversely affect the electrical connection performance.

To solve the above issues, the NT-Cu pad in the opening of the dielectric layer may be thinned to remove a large portion of the dielectric layer and a large portion of the irregular or less orderly crystal structures at peripheral regions of the NT-Cu pad. After the thinning operation, the inclined inner sidewalls remained are less curved and have a relatively small slope, and the remained bottom portion of the NT-Cu on the less inclined inner sidewall may have less irregular crystal structures. Therefore, the thinned NT-Cu pad may have a relatively dense structure, an improved structural strength, and a relatively high structural stability, and thus the thinned NT-Cu pad may be less easily oxidized, which is advantageous to improving the electrical performance of the NT-Cu pad as well as the package structure.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive through vias. In some arrangements, the substrate 10 may include a ceramic material, a semiconductor material, and/or a metal material. For example, the substrate 10 may be or include a wafer (e.g., a silicon wafer), a silicon-based submount, an interposer (e.g., a glass interposer), a ceramic substrate, and/or a metal plate. In some arrangements, the substrate 10 may include an organic substrate or a leadframe. The leadframe may be or include a pre-molded leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may include an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof.

The substrates 10A and 10B may be disposed over the substrate 10. In some arrangements, the substrates 10A and 10B are electrically connected to the substrate 10. The substrates 10A and 10B may be independently disposed over the substrate 10. The substrates 10A and 10B may independently include, for example, a printed circuit board, such as a paper-based copper foil laminate, a composite copper foil laminate, or a polymer-impregnated glass-fiber-based copper foil laminate. The substrates 10A and 10B may independently include an interconnection structure, such as a plurality of conductive traces and/or a plurality of conductive through vias. In some arrangements, the substrates 10A and 10B may independently include a ceramic material, a semiconductor material, and/or a metal material. For example, the substrates 10A and 10B may be or include a wafer (e.g., a silicon wafer), a silicon-based submount, an interposer (e.g., a glass interposer), a ceramic substrate, and/or a metal plate. In some arrangements, the substrates 10A and 10B may include an organic substrate or a leadframe. The leadframe may be or include a pre-molded leadframe. In some arrangements, the substrates 10A and 10B may independently include a two-layer substrate which includes a core layer and a conductive material and/or structure disposed on an upper surface and a bottom surface of the substrates 10A and 10B. The conductive material and/or structure may include a plurality of conductive traces. The substrates 10A and 10B may independently include an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof.

The conductive pads 110 and dielectric layers 120 and 130 may be disposed over the substrate 10. The conductive pads 110 may include a conductive material, such as a metal or metal alloy. Examples include gold (Au), silver (Ag), aluminum (Al), copper (Cu), or an alloy thereof. The dielectric layers 120 and 130 may include, for example, one or more organic materials (e.g., phosphoric anhydride (PA), polyimide (PI), polybenzoxazole (PBO), epoxy, and an epoxy-based material) or one or more inorganic materials (e.g., silicon oxide, silicon nitride, silicon oxynitride, glass, and ceramic). In some arrangements, the dielectric layer 120 is or includes silicon oxide, silicon nitride, or a combination thereof. In some arrangements, the dielectric layer 130 includes a photoresist material, e.g., PI, PBO, or a combination thereof.

The conductive pad 110A and dielectric layers 120A and 130A may be disposed over the substrate 10A. The conductive pad 110B and dielectric layers 120B and 130B may be disposed over the substrate 10B. The conductive pads 110A and 110B may independently include a conductive material, such as a metal or metal alloy. Examples include Au, Ag, Al, Cu, or an alloy thereof. The dielectric layers 120A, 120B, 130A, and 130B may independently include, for example, one or more organic materials (e.g., PA, PI, PBO, epoxy, and an epoxy-based material) or one or more inorganic materials (e.g., silicon oxide, silicon nitride, silicon oxynitride, glass, and ceramic). In some arrangements, the dielectric layers 120A and 120B independently are or include silicon oxide, silicon nitride, or a combination thereof. In some arrangements, the dielectric layers 130A and 130B independently include a photoresist material, e.g., PI, PBO, or a combination thereof.

The conductive elements 200 may be disposed over the substrate 10 and electrically connected to the conductive pads 110. The conductive elements 200A may be disposed over the substrate 10A and electrically connected to the conductive pads 110A. The conductive elements 200B may be disposed over the substrate 10B and electrically connected to the conductive pads 110B. The conductive elements 200, 200A, and 200B may independently have an anisotropic crystal structure. The anisotropic crystal structure may be or include a nanotwinned crystal structure. The term “nanotwinned” refers to two crystals (or two portions of a crystal) are formed mirrored across a common crystallographic plane. The nanotwinned crystal structure may include a plurality of grains each including a plurality of nanotwinned crystals (or “nanotwins”, “nanotwinned layers”, or “multi-layers”) stacked in the common crystallographic plane. The conductive elements 200, 200A, and 200B may be referred to as conductive pads or conductive vias. In some arrangements, the conductive elements 200, 200A, and 200B include nanotwinned copper (NT-Cu) pads or NT-Cu vias.

The seed layer 210 may be between the conductive pad 110 and the conductive element 200. The seed layer 210A may be between the conductive pad 110A and the conductive element 200A. The seed layer 210B may be between the conductive pad 110B and the conductive element 200B. The seed layers 210, 210A, and 210B may independently include, for example, titanium (Ti), copper (Cu), nickel (Ni), another metal, an alloy (such as a titanium-tungsten alloy (TiW)), or a combination thereof.

The conductive wire 30 may be electrically connected to the conductive element 200 and the conductive element 200A. In some arrangements, the conductive wire 30 includes end portions 310 and 330 and a wire portion 320. In some arrangements, the end portions 310 and 330 may independently include a ball bond or a stitch bond.

The reflowable element 40 may be electrically connected to the conductive element 200 and the conductive element 200B. In some arrangements, the conductive pad 110 is electrically connected to the conductive pad 110A through the conductive elements 200 and 200A and the reflowable element 40. The reflowable element 40 may include a solder material.

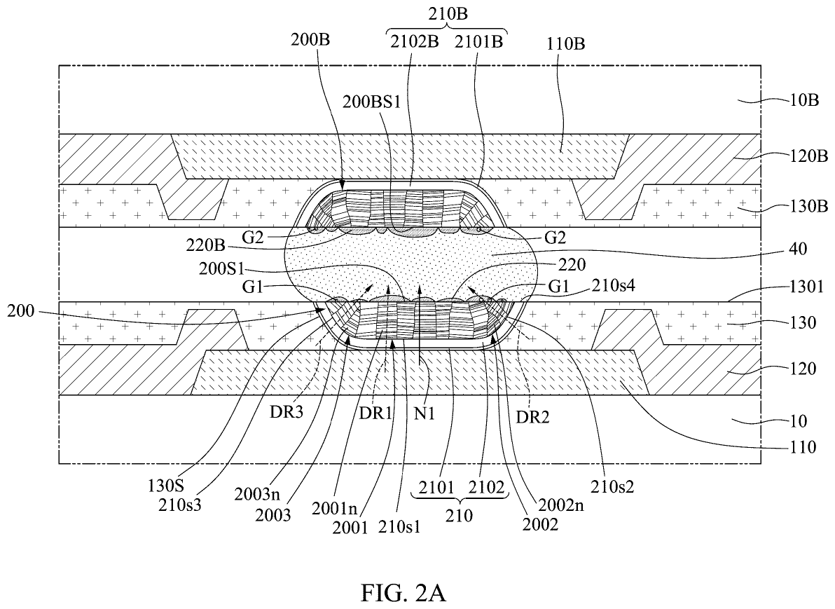

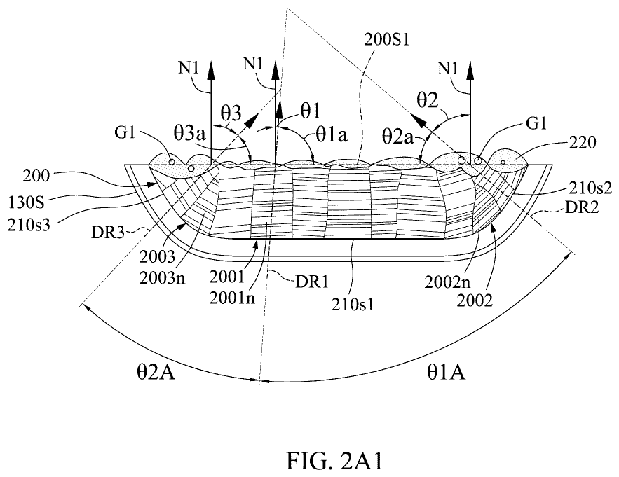

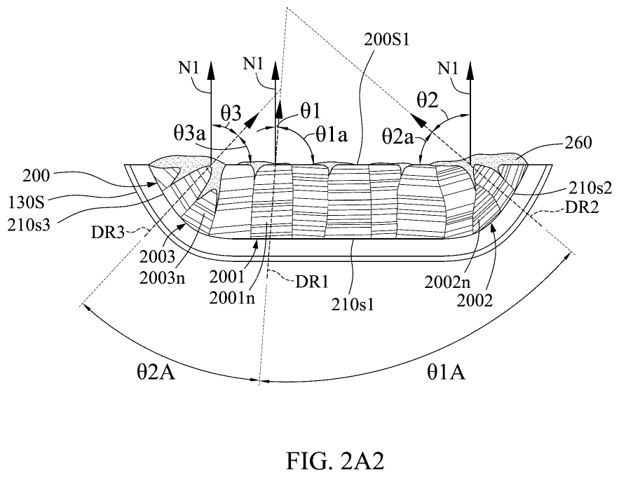

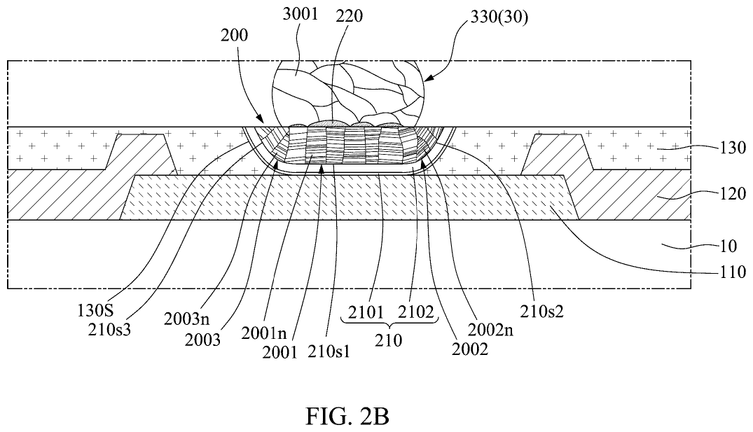

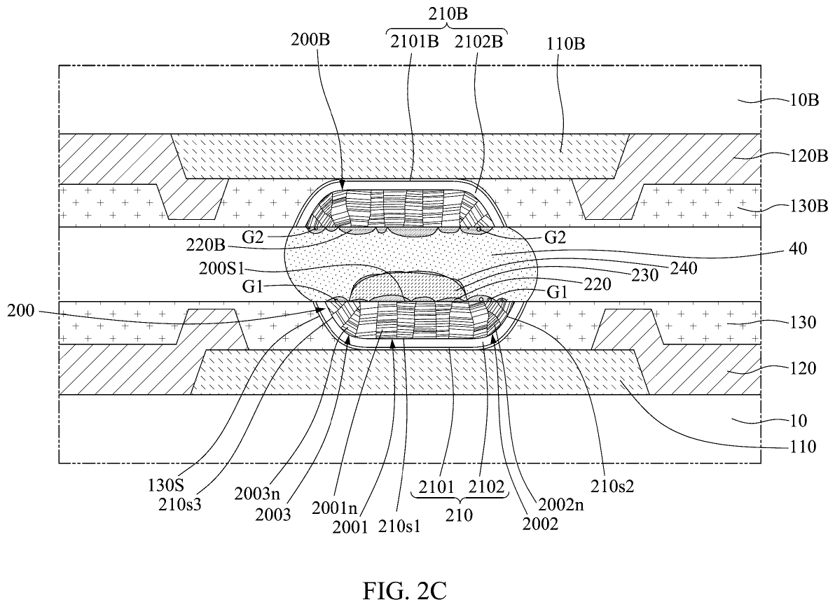

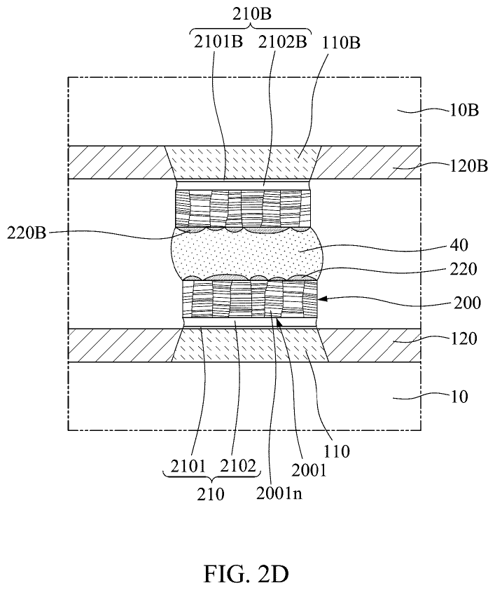

FIG. 2A is a cross-section of a portion of a package structure 1 in accordance with some arrangements of the present disclosure. FIG. 2A1 is a cross-section of a portion of a package structure 1 in accordance with some arrangements of the present disclosure. In some arrangements, FIG. 2A is a cross-section of a portion 2A of the package structure 1. In some arrangements, FIG. 2A1 illustrates a portion of the structure illustrated in FIG. 2A.

In some arrangements, the dielectric layer 130 is over the substrate 10 and has an opening 130C defined by one or more sloped sidewalls 130S. The dielectric layer 130 may have an upper surface 1301 (also referred to as “a top surface”).

In some arrangements, the seed layer 210 is between the conductive element 200 and the sloped sidewalls 130S. In some arrangements, the seed layer 210 is in the opening 130C and has a surface 210s1 and sloped lateral surfaces 210s2 and 210s3 substantially conformal with the sloped sidewalls 130S. The lateral surfaces 210s2 and 210s3 may be referred to as curved lateral surfaces. In some arrangements, the surface 210s1 is substantially parallel to the upper surface 200S1 of the conductive element 200, and the lateral surfaces 210s2 and 210s3 are inclined with respect to the surface 210s1. In some arrangements, an end surface 210s4 of the seed layer 210 is substantially aligned with the upper surface 1301 of the dielectric layer 130 and the upper surface 200S1 of the conductive element 200. In some arrangements, the seed layer 210 includes sub-layers 2101 and 2102. The sub-layer 2101 may be or include Ti, and the sub-layer 2102 may be or include Cu.

In some arrangements, the conductive element 200 is disposed in the opening 130C and includes an anisotropic crystal structure. In some arrangements, the conductive element 200 is disposed over the conductive pad 110. The conductive element 200 may have an upper surface 200S1 (also referred to as “a top surface” or “a bonding surface”) substantially aligned with the upper surface 1301 of the dielectric layer 130.

In some arrangements, the anisotropic crystal structure of the conductive element 200 has the upper surface 200S1. In some arrangements, an area of a [111] crystallographic plane of the upper surface 200S1 of the anisotropic crystal structure of the conductive element 200 is greater than an area of a non-[111] crystallographic plane of the upper surface 200S1 of the anisotropic crystal structure of the conductive element 200. In some arrangements, the area of the non-[111] crystallographic plane is less than 20% of an area of the upper surface 200S1. In some arrangements, a cross-sectional width of a [111] crystallographic plane of the upper surface 200S1 of the anisotropic crystal structure of the conductive element 200 is greater than a cross-sectional width of a non-[111] crystallographic plane of the upper surface 200S1 of the anisotropic crystal structure of the conductive element 200. In some arrangements, the cross-sectional width of the non-[111] crystallographic plane is less than 20% of a cross-sectional width of the upper surface 200S1. In some arrangements, the non-[111] crystallographic plane is at a peripheral region of the upper surface 200S1 of the conductive element 200. In some arrangements, the [111] crystallographic plane is over the surface 210s of the seed layer 210, and the non-[111] crystallographic plane is over the sloped lateral surfaces 210s2 and 210s3.

In some arrangements, the conductive element 200 (or the NT-Cu pad) includes crystal grains 2001, 2002, and 2003. In some arrangements, each of the crystal grains 2001, 2002, and 2003 includes a plurality of nanotwinned layers 2001n, 2002n, and 2003n (or “nanotwins,” “nanotwinned crystals,” or “multi-layers”) stacked in the common crystallographic plane. In some arrangements, the crystal structure of the crystal grain 2001 or the nanotwinned layers 2001n is more regular than the crystal structure of the crystal grain 2002 or the nanotwinned layers 2002n. In some arrangements, the crystal structure of the crystal grain 2001 or the nanotwinned layers 2001n is more regular than the crystal structure of the crystal grain 2003 or the nanotwinned layers 2003n. In some arrangements, the crystal grains 2001 (or the nanotwinned layers 2001n) are at or adjacent to a center region of the conductive element 200, and the crystal grains 2002 and 2003 (or the nanotwinned layers 2002n and 2003n) are at or adjacent to a peripheral region of the conductive element 200.

In some arrangements, the nanotwinned layers 2001n are stacked substantially along a direction DR1 from the surface 210s1 toward the upper surface 200S1. In some arrangements, the nanotwinned layers 2001n may have the [111] crystallographic plane of the upper surface 200S1. In some arrangements, the nanotwinned layers 2001n are spaced apart from the lateral surfaces 210s2 and 210s3 by the nanotwinned layers 2002n and 2003n. In some arrangements, the nanotwinned layers 2002n are stacked substantially along a direction DR2 from the lateral surface 210s2 toward the upper surface 200S 1. In some arrangements, the nanotwinned layers 2002n contact the lateral surface 210s2. In some arrangements, the nanotwinned layers 2002n may have the non-[111] crystallographic plane of the upper surface 200S1. In some arrangements, the [111] crystallographic plane of the nanotwinned layers 2002n is non-parallel to the upper surface 200S1. In some arrangements, the direction DR2 is different from the direction DR1. In some arrangements, the nanotwinned layers 2003n are stacked substantially along a direction DR3 from the lateral surface 210s3 toward the upper surface 200S1. In some arrangements, the nanotwinned layers 2003n contact the lateral surface 210s3. In some arrangements, the [111] crystallographic plane of the nanotwinned layers 2003n is non-parallel to the upper surface 200S1. In some arrangements, the nanotwinned layers 2003n may have the non-[111] crystallographic plane of the upper surface 200S1. In some arrangements, the direction DR3 is different from the directions DR1 and DR2. In some arrangements, the nanotwinned layers 2002n and 2003n are at peripheral regions of the conductive element 200, and the directions DR2 and DR3 are non-parallel to a normal line N1 of the upper surface 200S1 of the conductive element 200.

Referring to FIG. 2A1, in some arrangements, an angle θ1 defined by the direction DR1 and the normal line N1 is less than an angle θ2 defined by the direction DR2 and the normal line N1. In some arrangements, the angle θ1 defined by the direction DR1 and the normal line N1 is less than an angle θ3 defined by the direction DR3 and the normal line N1. In some arrangements the angle θ2 is different from the angle θ3. In some arrangements, an angle θ1a defined by the upper surface 200S1 and the normal line N1 is greater than an angle θ2a defined by the upper surface 200S1 and the normal line N1 and an angle θ3a defined by the upper surface 200S1 and the normal line N1. In some arrangements the angle θ2a is different from the angle θ3a. In some arrangements, the angle θ1A defined by the direction DR1 and the direction DR2 is different from the angle θ2A defined by the direction DR1 and the direction DR3. In some arrangements, the angle θ1A is greater than 0° and less than 90°. In some arrangements, the angle θ2A is greater than 0° and less than 90°.

In some arrangements, the conductive element 200 includes portions (e.g., the crystal grains 2002 and 2003) over the sloped sidewalls 130S and having a [111] crystallographic plane substantially parallel to the sloped sidewalls 130S. In some arrangements, the conductive element 200 further includes portions (e.g., crystal grains 2001) distinct from the above-mentioned portions (e.g., the crystal grains 2002 and 2003), and free from vertically overlapping the sloped sidewalls 130S and having a [111] crystallographic plane substantially parallel to the upper surface 1301 of the dielectric layer 130. In some arrangements, the [111] crystallographic plane of the portions (e.g., crystal grains 2001) of the conductive element 200 is substantially parallel to the upper surface 200S1 of the conductive element 200.

In some arrangements, the upper surface 200S1 of the conductive element 200 includes a first surface portion being an upper surface of a first portion of the conductive element 200 having nanotwinned layers stacked substantially along the direction DR2 and/or the direction DR3 (e.g., the crystal grains 2002 and/or the crystal grains 2003), and the upper surface 200S1 further includes a second surface portion being an upper surface of a second portion of the conductive element 200 having nanotwinned layers stacked substantially along the direction DR1 (e.g., the crystal grains 2001). In some arrangements, a width of the second surface portion (e.g., the upper surface of the crystal grains 2001) is greater than a width of the first surface portion (e.g., the upper surface of the crystal grains 2002 and/or the crystal grains 2003) from a cross-sectional view.

In some arrangements, the package structure 1 may further include an intermetallic (IMC) layer 220 contacting the nanotwinned layers 2001n, 2002n, and 2003n. In some arrangements, one or more voids G1 (also referred to as “air gaps”) may be formed between the IMC layer 220 and the nanotwinned layers 2002n and 2003n. In some arrangements, one or more voids G1 (or air gaps) may be formed between the IMC layer 220 and the non-[111] crystallographic plane of the anisotropic crystal structure of the conductive element 200. In some arrangements, the IMC layer 220 includes a first part contacting the upper surface of the crystal grains 2002 and/or crystal grains 2003, and the IMC layer 220 further includes a second part contacting the upper surface of the crystal grains 2001. In some arrangements, a thickness of the first part of the IMC layer 220 is greater than a thickness of the second part of the IMC layer 220. In some arrangements, a thickness of a portion of the IMC layer 220 contacting the crystal grains 2002 and/or 2003 is greater than a thickness of a portion of the IMC layer 220 contacting the crystal grains 2001. In some arrangements, the relatively thick IMC layer 220 formed on the nanotwinned layers 2002n and 2003n of the crystal grains 2002 and 2003 because they have relatively loose structure and less orderly crystal structures than the nanotwinned layers 2001n of the crystal grains 2001.

In some arrangements, the conductive element 200B is disposed over the conductive pad 110B and has an isotropic crystal structure. In some arrangements, the conductive element 200B has a lower surface 200BS1 including a [111] crystallographic plane of the anisotropic crystal structure and a non-[111] crystallographic plane of the anisotropic crystal structure, and an area of the non-[111] crystallographic plane is less than an area of the [111] crystallographic plane. The conductive element 200B is similar to the conductive element 200, and the description thereof is omitted hereinafter.

In some arrangements, the reflowable element 40 connects the conductive element 200B to the conductive element 200. In some arrangements, the reflowable element 40 contacts the crystallographic plane of the conductive element 200 and the [111] crystallographic plane of the conductive element 200B.

In some arrangements, the package structure 1 may further include an IMC layer 220B contacting the nanotwinned layers of the conductive element 200B. In some arrangements, one or more voids G2 (also referred to as “air gaps”) may be formed between the IMC layer 220B and the nanotwinned layers of the conductive element 200B. In some arrangements, one or more voids G2 (or air gaps) may be formed between the IMC layer 220 and the non-[111] crystallographic plane of the anisotropic crystal structure of the conductive element 200B.

In some arrangements, the seed layer 210A is between the conductive element 200B and the sloped sidewalls of the dielectric layer 130B. In some arrangements, the seed layer 210B is in an opening of the dielectric layer 130B and has sloped lateral surfaces substantially conformal with the sloped sidewalls of the dielectric layer 130B. In some arrangements, the seed layer 210B includes sub-layers 2101B and 2102B. The sub-layer 2101B may be or include Ti, and the sub-layer 2102B may be or include Cu.

FIG. 2A2 is a cross-section of a portion of a package structure 1 in accordance with some arrangements of the present disclosure. In some arrangements, FIG. 2A2 illustrates a portion of the structure illustrated in FIG. 2A.

In some arrangements, the package structure 1 further includes an oxide layer 260 over the upper surface 200S1 of the conductive element 200. In some arrangements, the oxide layer 260 includes a part (also referred to as “a first part”) extending between the nanotwinned layers 2002n, and the oxide layer 260 further includes a part (also referred to as “a second part”) extending between the nanotwinned layers 2001m. In some arrangements, the oxide layer 260 further includes a part (also referred to as “a third part”) extending between the nanotwinned layers 2003n. In some arrangements, a thickness of the first part is greater than a thickness of the second part. In some arrangements, a thickness of the third part is greater than the thickness of the second part. In some arrangements, the relatively thick oxide layer 260 formed on the nanotwinned layers 2002n and 2003n because the relatively loose structure of the less orderly crystal structures of the crystal grains 2002 and 2003 are prone to be oxidized than the nanotwinned layers 2001n of the crystal grains 2001 having more orderly crystal structures.

FIG. 2B is a cross-section of a portion of a package structure 1 in accordance with some arrangements of the present disclosure. In some arrangements, FIG. 2B is a cross-section of a portion 2B of the package structure 1.

In some arrangements, the end portion 330 of the conductive wire 30 includes crystal grains 3001. In some arrangements, the conductive wire 30 contacts the [111] crystallographic plane of the conductive element 200. In some arrangements, the IMC layer 220 contacts the [111] crystallographic plane of the conductive element 200 and the crystal grains 3001 of the conductive wire 30 and is substantially free of any void. In some arrangements, the non-[111] crystallographic plane of the conductive element 200 is substantially free from contacting the conductive wire 30.

In some arrangements, referring to FIG. 1 and FIG. 2B, the end portion 310 of the conductive wire 30 is similar to the end portion 330, the conductive element 200A is similar to the conductive element 200, the seed layer 210A is similar to the seed layer 210, and the description thereof is omitted hereinafter.

According to some arrangements of the present disclosure, an area of a [111] crystallographic plane of the upper surface 200S1 of the anisotropic crystal structure of the conductive element 200 is greater than an area of a non-[111] crystallographic plane of the upper surface 200S1 of the anisotropic crystal structure of the conductive element 200. As a result, the conductive element 200 (or the NT-Cu pad) includes a relatively large portion of regular crystal structure. Therefore, the conductive element 200 (or the NT-Cu pad) can have a relatively dense structure and a relatively high structural stability, and thus the conductive element 200 (or the NT-Cu pad) can be less easily oxidized, which is advantageous to improving the electrical performance of the conductive element 200 (or the NT-Cu pad) as well as the package structure 1.

FIG. 2C is a cross-section of a portion of a package structure 1 in accordance with some arrangements of the present disclosure. In some arrangements, FIG. 2C is a cross-section of a portion 2A of the package structure 1.

In some arrangements, the package structure 1 further includes a conductive bump 230 contacting the crystal grains 2001 or the [111] crystallographic plane of the anisotropic crystal structure of the conductive element 200. In some arrangements, the conductive bump 230 includes a conductive material. The conductive material may be different from materials of the reflowable element 40 and the conductive element 200. The conductive bump 230 may be or include Au.

In some arrangements, the reflowable element 40 contacts the conductive element 200 and the conductive bump 230. In some arrangements, the IMC layer 220 is between the conductive bump 230 and the crystal grains 2001, 2002, and 2003 of the conductive element 200. In some arrangements, the portion of the IMC layer 220 between the crystal grains 2001 and the conductive bump 230 is substantially free of any void. In some arrangements, one or more voids G1 may be formed between the crystal grains 2002 and 2003 and a portion of the IMC layer 220 between the conductive element 200 and the reflowable element 40.

According to some arrangements of the present disclosure, the conductive bump 230 can increase the contact surface with the reflowable element 40. Therefore, the bonding strength can be increased.

FIG. 2D is a cross-section of a portion of a package structure 1 in accordance with some arrangements of the present disclosure. In some arrangements, FIG. 2D is a cross-section of a portion 2A of the package structure 1.

In some arrangements, the upper surface 200S1 of the anisotropic structure of the conductive element 200 is substantially free of a non-[111] crystallographic plane.

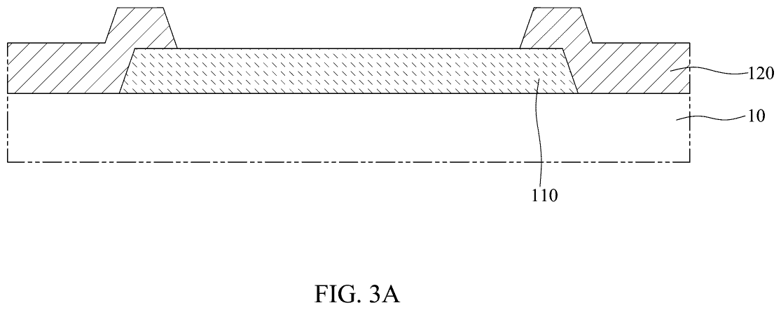

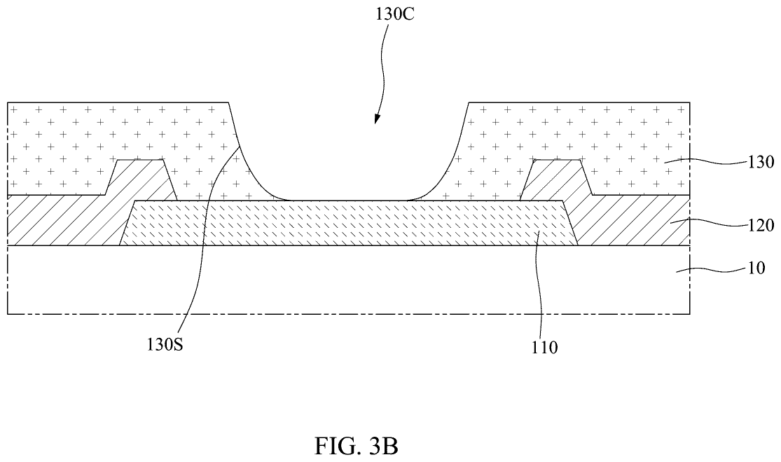

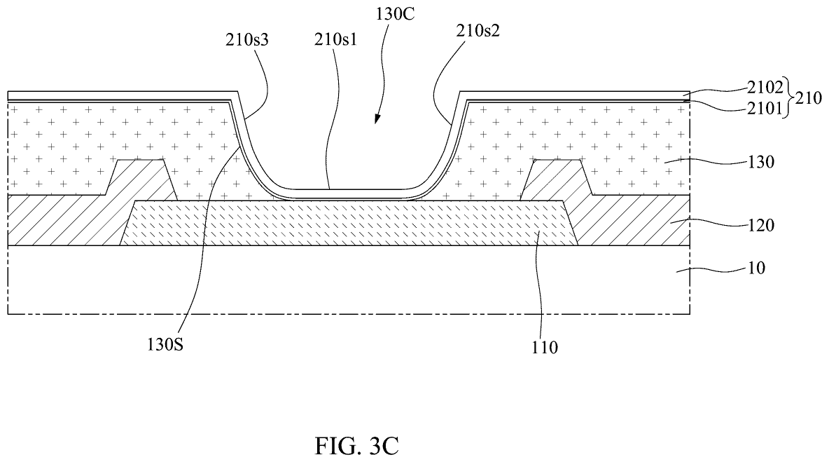

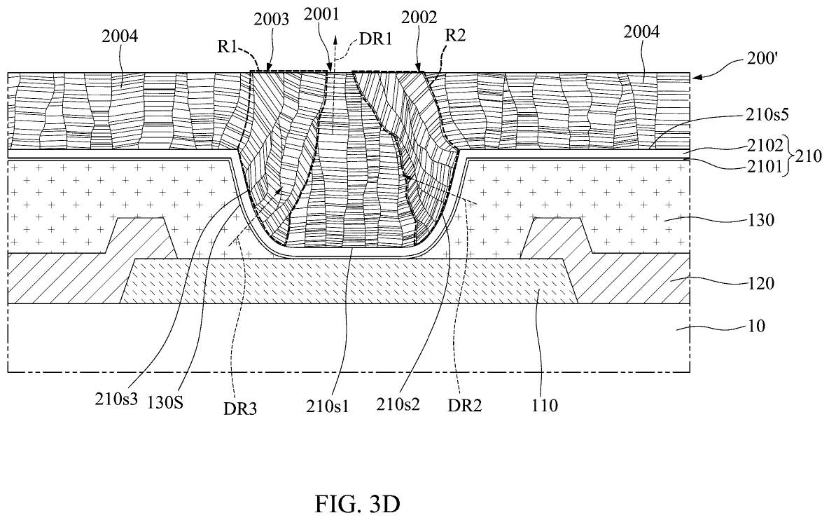

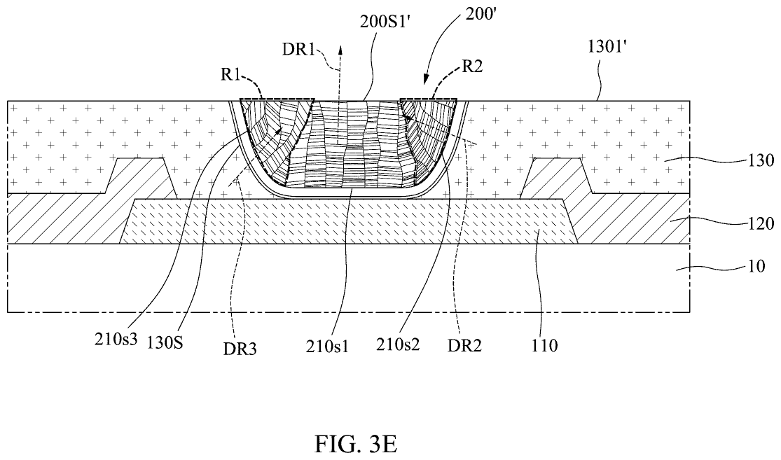

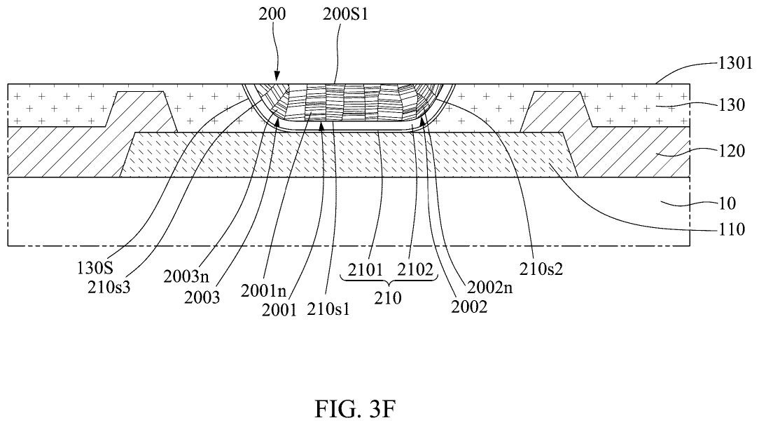

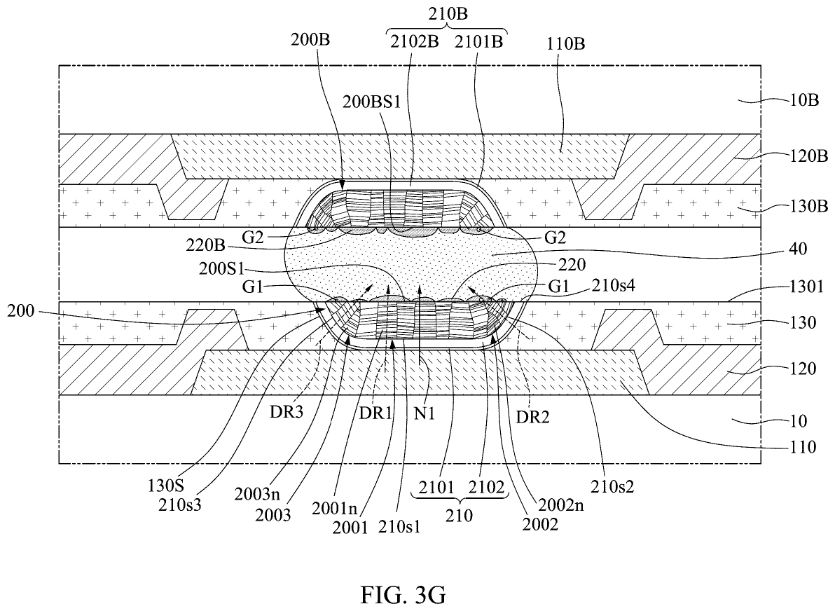

FIG. 3A, FIG. 3B, FIG. 3C, FIG. 3D, FIG. 3E, FIG. 3F, and FIG. 3G illustrate various stages of an example of a method for manufacturing a package structure 1 in accordance with some arrangements of the present disclosure. In some arrangements, FIG. 3A, FIG. 3B, FIG. 3C, FIG. 3D, FIG. 3E, FIG. 3F, and FIG. 3G illustrate various stages of an example of a method for manufacturing a portion 2A of a package structure 1 in accordance with some arrangements of the present disclosure.

Referring to FIG. 3A, a substrate 10 may be provided, a conductive pad 110 may be disposed or formed on the substrate 10, and a dielectric layer 120 may be disposed or formed on the conductive pad 110 and expose a portion of the conductive pad 110.

Referring to FIG. 3B, a dielectric layer 130 may be disposed or formed on the dielectric layer 120, and an opening 130C may be formed in the dielectric layer 130 to expose a portion of the conductive pad 110. The opening 130C may be defined by a sloped sidewall 130S of the dielectric layer 130. The dielectric layer 130 may be formed by coating.

Referring to FIG. 3C, a seed layer 210 may be formed over the dielectric layer 130 and a portion of the conductive pad 110 exposed by the opening 130C. The seed layer 210 may be formed on the sloped sidewalls 130S of the dielectric layer 130. The seed layer 210 may include sub-layers 2101 and 2102. The seed layer 210 may be formed by sputtering.

Referring to FIG. 3D, a conductive element 200′ may be formed over the seed layer 210. In some arrangements, the conductive element 200′ includes crystal grains 2001 formed on the surface 210s1, crystal grains 2002 formed on the sloped lateral surface 210s2, crystal grains 2003 formed on the sloped lateral surface 210s3, and crystal grains 2004 formed on the surface 210s5. The conductive element 200′ (or the crystal grains 2001, 2002, 2003, and 2004) may be formed by plating.

In some arrangements, the crystal grains 2001 and 2004 are formed on relatively flat surfaces 210s1 and 210s5, the crystal grains 2002 and 2003 are formed on sloped lateral surfaces 210s2 and 210s 3, and thus the crystal structures of the crystal grains 2002 and 2003 are less regular than the crystal structures of the crystal grains 2001 and 2004. In some arrangements, regions R1 and R2 of the conductive element 200′ over the sloped lateral surfaces 210s2 and 210s3 have relatively irregular crystal structures. In some arrangements, the nanotwinned layers of the crystal grains 2001 and 2004 are stacked along the direction DR1 that is substantially perpendicular to the surfaces 210s1 and 210s5. In some arrangements, the nanotwinned layers of the crystal grains 2002 are stacked along the direction DR2 that is substantially perpendicular to the lateral surface 210s2. In some arrangements, the nanotwinned layers of the crystal grains 2003 are stacked along the direction DR3 that is substantially perpendicular to the lateral surface 210s3. During the growth process, the nanotwinned layers of the crystal grains 2002 and 2003 may be blocked and compressed by the neighboring nanotwinned layers of the crystal grains 2001 that are also growing, and the crystal structures of the crystal grains 2002 and 2003 are less regular or less orderly than the crystal structure of the crystal grains 2001.

Referring to FIG. 3E and FIG. 3F, a thinning operation may be performed on the conductive element 200′ and the dielectric layer 130 to form a thinned conductive element 200 and a thinned dielectric layer 130. In some arrangements, relatively large portions of the regions R1 and R2 of the conductive element 200′ are removed. In some arrangements, relatively large portions of irregular crystal structures of the conductive element 200′ are removed. In some arrangements, referring to FIG. 3E, in the beginning stage of the thinning operation, the portions of the conductive element 200′ and the seed layer 210 are removed to expose an upper surface 1301′ of the dielectric layer 130 and an upper surface 200S1′ of the thinned conductive element 200′. As shown in FIG. 3E, the dielectric layer 130 is not thinned yet, and large portions of the regions R1 and R2 (e.g., the relatively irregular crystal structures of the crystal grains 2002 and 2003) are exposed and form portions of the upper surface 200S1′. At this beginning stage, the upper surface 200S1′ includes a large portion that is not an [111] crystallographic plane of nanotwinned layers. In some arrangements, as the grinding operation continues, the dielectric layer 130 is thinned by removing a portion of the dielectric layer 130 to form an upper surface 1301, and the conductive element 200′ is further thinned by removing relatively large portions of the regions R1 and R2 of the conductive element 200′ to form an upper surface 200S1. In some arrangements, the upper surface 200S1 of the conductive element 200 is substantially aligned with the upper surface 1301 of the dielectric layer 130. The thinning operation may be or include a grinding operation. After the thinning operation is completed by thinning the conductive element 200′ and the dielectric layer 130, the upper surface 200S1 only includes a relatively small portion that is not an [111] crystallographic plane of nanotwinned layers, and a relatively large portion of the upper surface 200S1 includes an crystallographic plane of nanotwinned layers, which is advantageous to bonding to conductive elements (e.g., solder balls, conductive pads, conductive wires, or the like.

Referring to FIG. 3G, operations similar to those illustrated in FIGS. 3A-3F may be performed to form a substrate 10B, a conductive pad 110B, dielectric layers 120B and 130B, and a conductive element 200B, and the conductive element 200B may be connected to the conductive element 200 through a reflowable element 40. As such, the portion 2A of the package structure 1 illustrated in FIG. 1 and FIG. 2A may be formed.

In some arrangements, a substrate 10A may be disposed on the substrate 10, and operations similar to those illustrated in FIGS. 3A-3E may be performed to form a conductive pad 110A, dielectric layers 120A and 130A, and a conductive element 200A. Next, a conductive wire 30 may be provided to connect the conductive element 200A to the conductive element 200. As such, the package structure 1 illustrated in FIG. 1 may be formed.

According to some arrangements of the present disclosure, the conductive element 200′ (or the NT-Cu pad) in the opening 130C of the dielectric layer 130 is thinned to remove a large portion of the dielectric layer 130 and a large portion of irregular or less orderly crystal structures at peripheral regions of the conductive element 200′ (or the NT-Cu pad). After the thinning operation, the inclined inner sidewalls remained are less curved and have a relatively small slope, and the thinned conductive element 200 on the less inclined inner sidewall may have less irregular crystal structures. Therefore, the thinned conductive element 200 (or the thinned NT-Cu pad) can have a relatively dense structure and a relatively high structural stability, and thus the thinned conductive element 200 (or the thinned NT-Cu pad) can be less easily oxidized, which is advantageous to improving the electrical performance of the conductive element 200 as well as the package structure 1.

In addition, according to some arrangements of the present disclosure, the conductive element 200′ (or the NT-Cu pad) is thinned to form the conductive element 200 configured to electrically connect to another conductive element (e.g., the conductive element 200B). Therefore, the thickness of the entire package structure 1 can be reduced, which is advantageous to the reduction of the package size.

Moreover, conventionally, different separated terminals are usually formed by forming a patterned photoresist having multiple openings over a single seed layer, forming multiple NT-Cu pads in the multiple openings, removing the patterned photoresist, and removing portions of the seed layer between the NT-Cu pads to separate the single seed layer into separate seed layers each corresponding to a NT-Cu pad. In contrast, referring to FIG. 1 and FIGS. 3D-3E, according to some arrangements of the present disclosure, the thinning operation can remove portions of the seed layer 210 so as to form separate seed layers 210 each corresponding to a conductive element 200. Therefore, the different terminals (e.g., the different conductive elements 200) can be defined by one thinning operation (or one grinding operation) without performing the above multiple operations. Accordingly, the manufacturing process is simplified, and the cost is reduced as well.

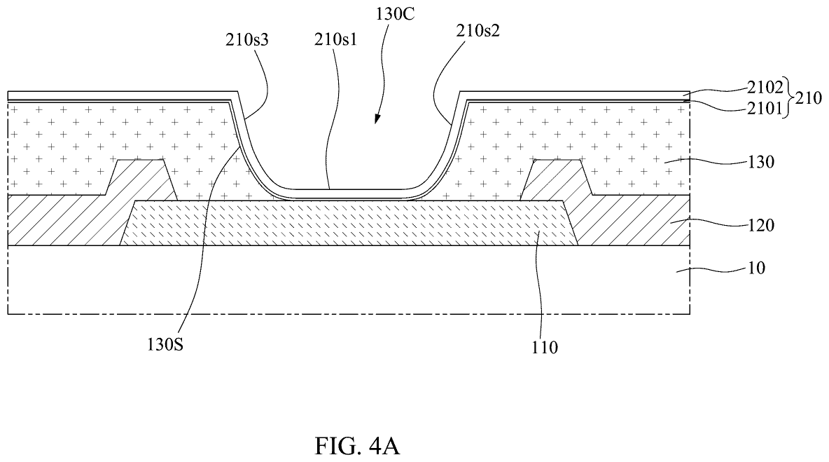

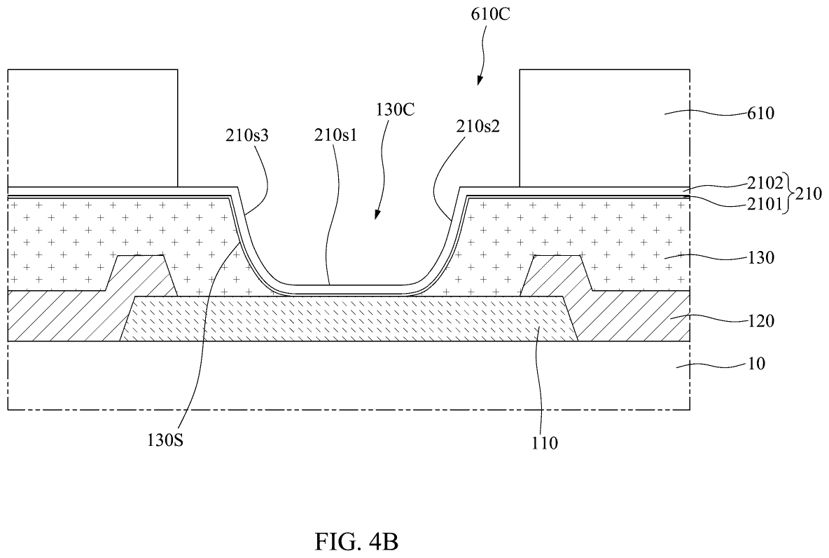

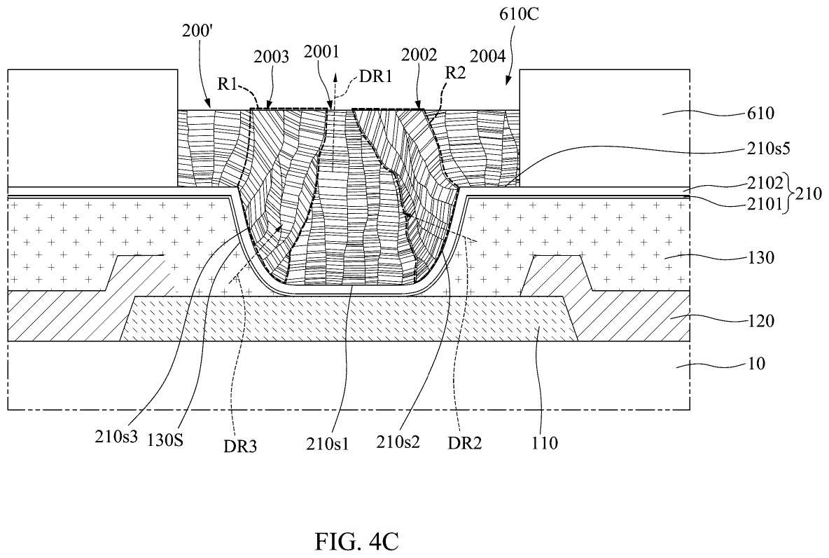

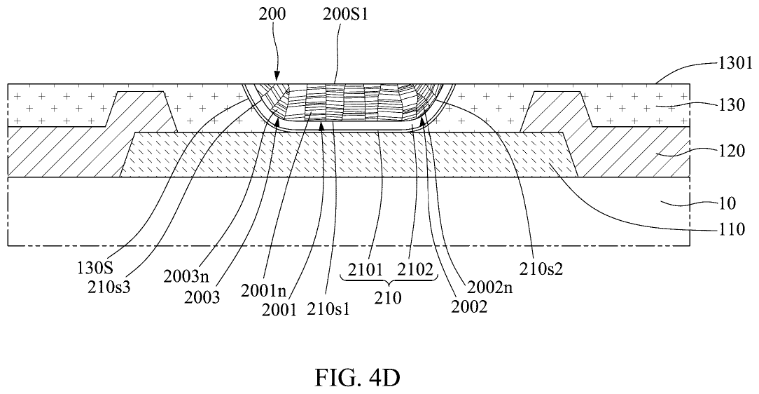

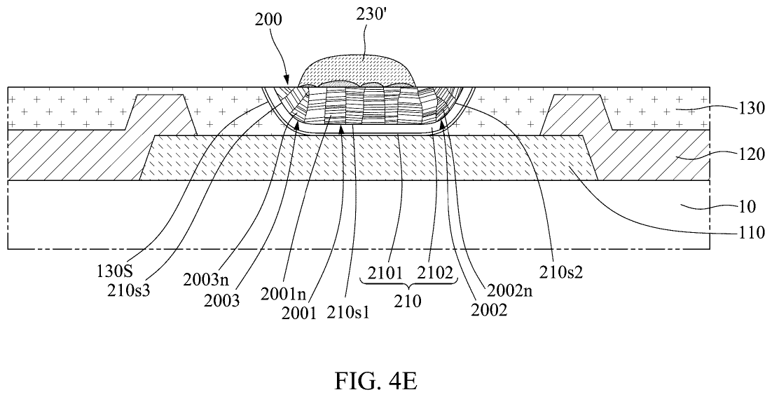

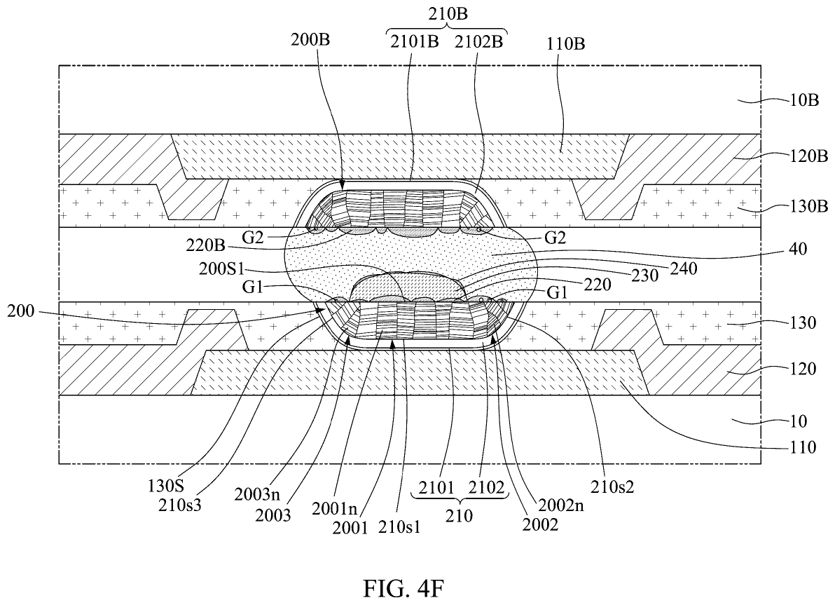

FIG. 4A, FIG. 4B, FIG. 4C, FIG. 4D, FIG. 4E, and FIG. 4F illustrate various stages of an example of a method for manufacturing a package structure 1 in accordance with some arrangements of the present disclosure. In some arrangements, FIG. 4A, FIG. 4B, FIG. 4C, FIG. 4D, FIG. 4E, and FIG. 4F illustrate various stages of an example of a method for manufacturing a portion 2A of a package structure 1 in accordance with some arrangements of the present disclosure.

Referring to FIG. 4A, operations similar to those illustrated in FIGS. 3A-3C may be performed to form a structure illustrated in FIG. 4A.

Referring to FIG. 4B, a photoresist 610 having an opening 610C may be formed over the seed layer 210 to expose the opening 130C. The photoresist 610 may be formed by coating.

Referring to FIG. 4C, operations similar to those illustrated in FIG. 3D may be performed to form a conductive element 200′ on the seed layer 210 in the opening 130C.

Referring to FIG. 4D, operations similar to those illustrated in FIG. 3E may be performed to form the thinned conductive element 200 and the thinned dielectric layer 130.

Referring to FIG. 4E, a conductive bump 230′ may be formed on the crystal grains 2001 or the [111] crystallographic plane of the anisotropic structure of the conductive element 200.

Referring to FIG. 4F, operations similar to those illustrated in FIG. 3E may be performed to form the portion 2A of the package structure 1 illustrated in FIG. 1 and FIG. 2C.

According to some arrangements of the present disclosure, the conductive element 200 is formed in the opening 620C defined by the photoresist 620. Therefore, the amount of the material of the conductive element 200 can be reduced, and thus the cost can be reduced.

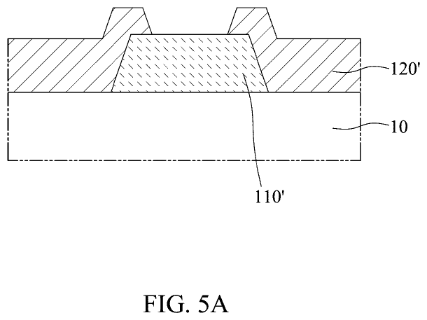

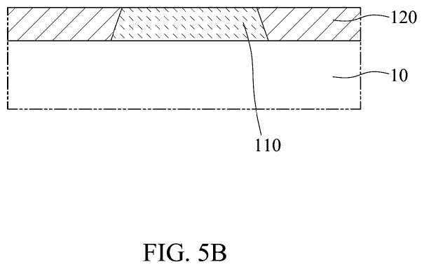

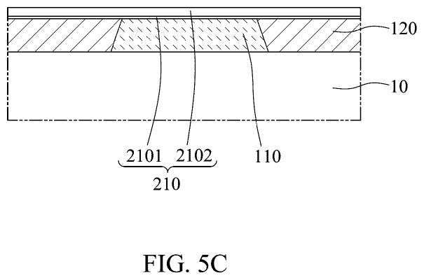

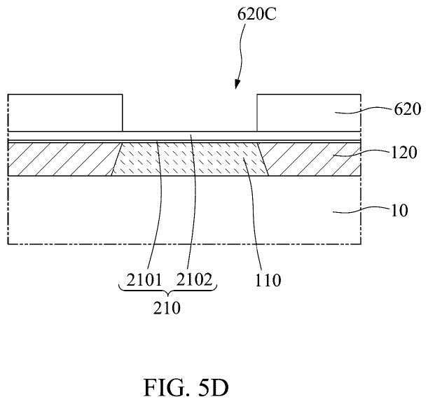

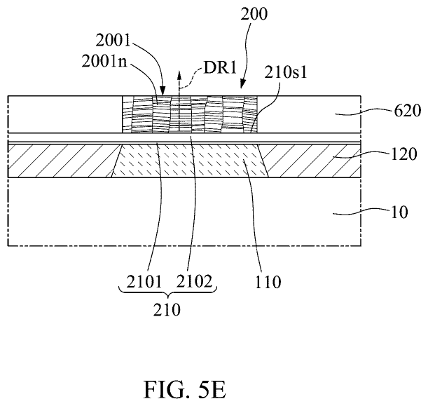

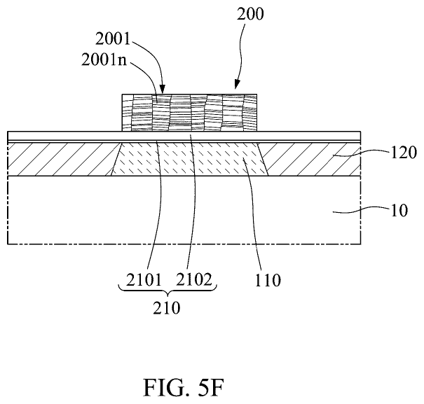

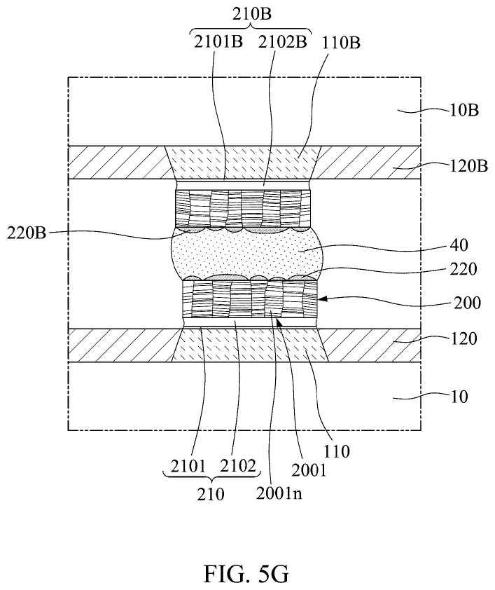

FIG. 5A, FIG. 5B, FIG. 5C, FIG. 5D, FIG. 5E, FIG. 5F, and FIG. 5G illustrate various stages of an example of a method for manufacturing a package structure 1 in accordance with some arrangements of the present disclosure. In some arrangements, FIG. 5A, FIG. 5B, FIG. 5C, FIG. 5D, FIG. 5E, FIG. 5F, and FIG. 5G illustrate various stages of an example of a method for manufacturing a portion 2A of a package structure 1 in accordance with some arrangements of the present disclosure.

Referring to FIG. 5A, a substrate 10 may be provided, a conductive pad 110′ may be disposed or formed on the substrate 10, and a dielectric layer 120′ may be disposed or formed on the conductive pad 110′ and expose a portion of the conductive pad 110′.

Referring to FIG. 5B, a thinning operation may be performed to remove portions of the conductive pad 110′ and the dielectric layer 120′ to form a thinned conductive pad 110 and a thinned dielectric layer 120. In some arrangements, an upper surface of the conductive pad 110 is substantially aligned with an upper surface of the dielectric layer 120.

Referring to FIG. 5C, a seed layer 210 may be formed over the dielectric layer 120 and a portion of the conductive pad 110 exposed by the dielectric layer 120. The seed layer 210 may be formed on a relatively flat surface formed of the substantially aligned upper surfaces of the conductive pad 110 and the dielectric layer 120. The seed layer 210 may include sub-layers 2101 and 2102. The seed layer 210 may be formed by sputtering.

Referring to FIG. 5D, a photoresist 620 having an opening 620C may be formed over the seed layer 210 to expose a portion of the seed layer 210 over the conductive pad 110. The photoresist 620 may be formed by coating.

Referring to FIG. 5E, operations similar to those illustrated in FIG. 3D may be performed to form a conductive element 200 on the seed layer 210 in the opening 620C. In some arrangements, since the crystal grains 2001 of the anisotropic structure of the conductive element 200 is formed on a relatively flat surface 210s1, the as-formed nanotwinned layers 2001n of the crystal grains 2001 include relatively regular crystal structures. In some arrangements, the conductive element 200 is substantially free of the crystal grains 2002 and 2003 having relatively irregular crystal structures.

Referring to FIG. 5F, the photoresist 620 may be removed.

Referring to FIG. 5G, operations similar to those illustrated in FIG. 3E may be performed to form the portion 2A of the package structure 1 illustrated in FIG. 1 and FIG. 2D.

According to some arrangements of the present disclosure, the conductive pad 110′ and the dielectric layer 120′ are thinned to provide a relatively flat surface for forming the conductive element 200 (or the NT-Cu pad). Therefore, the nanotwinned layers of the conductive element 200 are formed on a substantially flat surface instead of sloped surfaces, and thus the as-formed nanotwinned layers can form a relatively regular crystal structure of the conductive element 200. Accordingly, the as-formed conductive element 200 (or the NT-Cu pad) can have a relatively dense structure and a relatively high structural stability, and thus the conductive element 200 (or the NT-Cu pad) can be less easily oxidized, which is advantageous to improving the electrical performance of the conductive element 200 as well as the package structure 1.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a first substrate;
a first dielectric layer over the first substrate and having an opening defined by a sloped sidewall; and
a first conductive element disposed in the opening and having an upper surface, wherein the first conductive element comprises a first portion over the sloped sidewall and a second portion distinct from the first portion,
wherein the first portion comprises a plurality of first nanotwinned layers stacked substantially along a first direction, the second portion comprises a plurality of second nanotwinned layers stacked substantially along a second direction, and an angle defined by the first direction and the second direction is greater than 0° and less than 90°, and
wherein the upper surface comprises a first surface portion being an upper surface of the first portion and having a first width in a cross-sectional view, and the upper surface further comprises a second surface portion being an upper surface of the second portion and having a second width greater than the first width in the cross-sectional view.

2. The package structure as claimed in claim 1, further comprising an intermetallic (IMC) layer comprising a first part contacting the first surface portion of the upper surface of the first conductive element and a second part contacting the second surface portion of the upper surface of the first conductive element, wherein a thickness of the first part is greater than a thickness of the second part.

3. The package structure as claimed in claim 2, wherein an upper surface of the first dielectric layer is substantially aligned with the upper surface of the first conductive element, and the second portion has a [111] crystallographic plane substantially parallel to the upper surface of the first dielectric layer.

4. The package structure as claimed in claim 1, further comprising an oxide layer comprising a first part extending between the first nanotwinned layers and a second part extending between the second nanotwinned layers, wherein a thickness of the first part is greater than a thickness of the second part.

5. The package structure as claimed in claim 1, further comprising a seed layer between the first conductive element and the sloped sidewall of the first dielectric layer.

6. The package structure as claimed in claim 5, wherein an end surface is substantially aligned with an upper surface of the dielectric layer and the upper surface of the first conductive element.

7. A package structure, comprising:
a first substrate comprising a first pad; and
a first conductive element disposed over the first pad, wherein the first conductive element has an upper surface and comprises an anisotropic crystal structure having the upper surface,
wherein a cross-sectional width of a [111] crystallographic plane of the upper surface of the anisotropic crystal structure is greater than a cross-sectional width of a non-[111] crystallographic plane of the upper surface of the anisotropic crystal structure.

8. The package structure as claimed in claim 7, wherein the cross-sectional width of the non-[111] crystallographic plane is less than 20% of a cross-sectional width of the upper surface.

9. The package structure as claimed in claim 7, wherein the non-[111] crystallographic plane is at a peripheral region of the upper surface of the first conductive element.

10. The package structure as claimed in claim 7, wherein the first conductive element comprises:
a plurality of first nanotwinned layers stacked substantially along a first direction and having the [111] crystallographic plane; and
a plurality of second nanotwinned layers stacked substantially along a second direction different from the first direction and having the non-[111] crystallographic plane.

11. The package structure as claimed in claim 10, wherein the second nanotwinned layers are at a peripheral region of the first conductive element, and the second direction is non-parallel to a normal line of the upper surface of the first conductive element.

12. The package structure as claimed in claim 10, further comprising an intermetallic (IMC) layer contacting the first nanotwinned layers and the second nanotwinned layers, wherein at least a void is formed between the IMC layer and the second nanotwinned layers.

13. The package structure as claimed in claim 7, further comprising:
a second substrate comprising a second pad; and
a second conductive element disposed over the second pad and having an anisotropic crystal structure, wherein the second conductive element has a lower surface comprising a [111] crystallographic plane of the anisotropic crystal structure and a non-[111] crystallographic plane of the anisotropic crystal structure having an area less than an area of the [111] crystallographic plane; and
a reflowable element connecting the second conductive element to the first conductive element.

14. The package structure as claimed in claim 13, wherein the reflowable element contacts the crystallographic plane of the first conductive element and the [111] crystallographic plane of the second conductive element.

15. A package structure, comprising:
a first substrate;
a first seed layer over the first substrate and having a curved lateral surface; and
a first conductive element disposed on the first seed layer and comprising an anisotropic crystal structure, wherein the first conductive element comprises a first portion contacting the curved lateral surface and having a [111] crystallographic plane non-parallel to an upper surface of the first conductive element, and the anisotropic crystal structure of the first conductive element further comprises a second portion spaced apart from the curved lateral surface of the first seed layer by the first portion.

16. The package structure as claimed in claim 15, wherein a crystal structure of the second portion is more regular than a crystal structure of the first portion.

17. The package structure as claimed in claim 15, wherein the second portion comprises a plurality of nanotwinned layers arranged substantially regularly in a columnar shape, and the first portion comprises a plurality of nanotwinned layers arranged in a manner less regularly than the nanotwinned layers of the second portion.

18. The package structure as claimed in claim 15, further comprising a conductive bump contacting the second portion of the anisotropic crystal structure of the first conductive element.

19. The package structure as claimed in claim 18, further comprising:
a reflowable element contacting the first conductive element and the conductive bump;
a first intermetallic (IMC) layer between the conductive bump and the second portion of the first conductive element; and
a second IMC layer between the reflowable element and the first portion of the first conductive element.

20. The package structure as claimed in claim 19, wherein the first IMC layer is substantially free of any void, and at least a void is formed between the second IMC layer and the first portion of the first conductive element.
